(19) United States
(12) Patent Application Publication
(10) Pub. No.: US 2026/0007018 A1
(43) Pub. Date: Jan. 1, 2026

(54) DISPLAY APPARATUS AND ELECTRONIC DEVICE INCLUDING THE SAME

(71) Applicant: Samsung Display Co., Ltd., Yongin-si (KR)

(72) Inventors: Sujin Lee, Yongin-si (KR); Yujin Lee, Yongin-si (KR); Mindo Heo, Yongin-si (KR)

(21) Appl. No.: 19/250,900

(22) Filed: Jun. 26, 2025

(30) Foreign Application Priority Data
Jun. 27, 2024 (KR) 10-2024-0084817

(51) Int. Cl. H10K 59/131; H10K 59/126

(52) U.S. Cl. CPC H10K 59/131; H10K 59/126

(57) ABSTRACT

A display apparatus includes a substrate comprising a display region and a peripheral region outside the display region, a common voltage supply unit in the peripheral region and surrounding at least a portion of the display region, a common voltage line electrically connected to the common voltage supply unit and comprising a horizontal common voltage line extending in a first direction and a vertical common voltage line extending in a second direction crossing the first direction, a data line in the display region and extending in the second direction, a horizontal connection line in the display region, extending in the first direction, and comprising an opening, and a vertical connection line in the display region, extending in the second direction, and passing through the opening, wherein the common voltage line covers the opening in the horizontal connection line.

### CROSS-REFERENCE TO RELATED APPLICATION

The present application claims priority to and the benefit of Korean Patent Application No. 10-2024-0084817, filed on Jun. 27, 2024, in the Korean Intellectual Property Office, the entire disclosure of which is incorporated herein by reference.

### BACKGROUND

### 1. Field

Aspects of one or more embodiments relate to a display apparatus and an electronic device including the same.

### 2. Description of the Related Art

Display apparatuses visually display data. Display apparatuses may provide images by using light-emitting diodes. Applications of display apparatuses have diversified, and various designs for improving the quality of display apparatuses have been attempted.

The above information disclosed in this Background section is only for enhancement of understanding of the background and therefore the information discussed in this Background section does not necessarily constitute prior art.

### SUMMARY

Aspects of one or more embodiments include a display apparatus.

Additional aspects will be set forth in part in the description which follows and, in part, will be apparent from the description, or may be learned by practice of the presented embodiments of the disclosure.

According to some embodiments of the present disclosure, a display apparatus includes a substrate including a display region and a peripheral region outside the display region, a common voltage supply unit arranged in the peripheral region and surrounding at least a portion of the display region, a common voltage line electrically connected to the common voltage supply unit and including a horizontal common voltage line extending in a first direction and a vertical common voltage line extending in a second direction crossing the first direction, a data line arranged in the display region and extending in the second direction, a horizontal connection line arranged in the display region, extending in the first direction, and including an opening, and a vertical connection line arranged in the display region, extending in the second direction, and passing through the opening, wherein the common voltage line is arranged to cover the opening in the horizontal connection line.

According to some embodiments, the horizontal common voltage line and the vertical common voltage line may be integrally formed with each other as a single body.

According to some embodiments, the common voltage line may include a first shielding pattern, and the first shielding pattern may be arranged to cover the opening in the horizontal connection line.

According to some embodiments, the horizontal common voltage line, the vertical common voltage line, and the first shielding pattern may be integrally formed with one another as a single body.

According to some embodiments, the vertical connection line may be located above the horizontal connection line, and the common voltage line and the first shielding pattern may be located above the vertical connection line.

According to some embodiments, a display apparatus includes a substrate including a display region and a peripheral region outside the display region, a common voltage supply unit arranged in the peripheral region and surrounding at least a portion of the display region, a horizontal common voltage line electrically connected to the common voltage supply unit and extending in a first direction, a first vertical common voltage line electrically connected to the common voltage supply unit and extending in a second direction crossing the first direction, a data line arranged in the display region and extending in the second direction, a horizontal connection line arranged in the display region and extending in the first direction, and a first vertical connection line arranged in the display region, extending in the second direction, and electrically connected to the common voltage supply unit, wherein the first vertical common voltage line includes a first conductive pattern, and the first vertical common voltage line and the first vertical connection line are electrically connected to each other via a first contact hole in the first conductive pattern.

According to some embodiments, the display apparatus may further include an organic light-emitting diode on the first vertical common voltage line and including a pixel electrode, an emission layer, and an opposite electrode.

According to some embodiments, the pixel electrode may be arranged to cover the first contact hole and the first conductive pattern.

According to some embodiments, the first vertical common voltage line and the first conductive pattern may be integrally formed with each other as a single body.

According to some embodiments, the display apparatus may further include a second vertical connection line spaced apart from the first vertical connection line in the first direction, extending in the second direction, and electrically connected to the common voltage supply unit.

According to some embodiments, the display apparatus may further include a second vertical common voltage line spaced apart from the first vertical common voltage line in the first direction, extending in the second direction, and electrically connected to the common voltage supply unit.

According to some embodiments, the second vertical common voltage line may include the first conductive pattern, and the second vertical common voltage line and the second vertical connection line may be electrically connected to each other via the first contact hole in the first conductive pattern.

According to some embodiments, the first vertical common voltage line, the second vertical common voltage line, and the first conductive pattern may be integrally formed with one another as a single body.

According to some embodiments of the present disclosure, a display apparatus includes a substrate including a display region and a peripheral region outside the display region, a common voltage supply unit arranged in the peripheral region and surrounding at least a portion of the display region, a driving voltage supply unit arranged in the peripheral region, a common voltage line including a horizontal common voltage line electrically connected to the common voltage supply unit and extending in a first direction and a vertical common voltage line electrically connected to the common voltage supply unit and extending in a second direction crossing the first direction, a first vertical connection line arranged in the display region, extending in the second direction, electrically connected to the driving voltage supply unit, and including a first conductive pattern and a second conductive pattern, and a second vertical connection line spaced apart from the first vertical connection line in the first direction, extending in the second direction, electrically connected to the common voltage supply unit, and including a third conductive pattern and a fourth conductive pattern, wherein the first conductive pattern and the third conductive pattern may be spaced apart from each other in the first direction, the second conductive pattern and the fourth conductive pattern may be spaced apart from each other in the first direction, the first conductive pattern may include a first contact hole, the fourth conductive pattern may include a second contact hole, and a first shielding pattern, a second shielding pattern, a third shielding pattern, and a fourth shielding pattern on the first vertical connection line and the second vertical connection line may be respectively arranged to cover the first conductive pattern, the second conductive pattern, the third conductive pattern, and the fourth conductive pattern.

According to some embodiments, the first conductive pattern and the second conductive pattern may be integrally formed with the first vertical connection line, and the third conductive pattern and the fourth conductive pattern may be integrally formed with the second vertical connection line.

According to some embodiments, the first vertical connection line and the second vertical connection line may be arranged in a same layer and may include a same material.

According to some embodiments, the first to fourth shielding patterns and the common voltage line may be arranged in a same layer and may include a same material.

According to some embodiments, the second shielding pattern, the fourth shielding pattern, and the horizontal common voltage line may be integrally formed with one another as a single body.

According to some embodiments, the horizontal common voltage line may be electrically connected to the second vertical connection line.

According to some embodiments, the third shielding pattern, the fourth shielding pattern, and the vertical common voltage line may be integrally formed with one another as a single body.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view schematically showing a display apparatus according to some embodiments;

FIG. 2 is a side view schematically showing the display apparatus shown in FIG. 1;

FIG. 3 is an equivalent circuit view schematically showing a pixel circuit electrically connected to a light-emitting diode corresponding to a pixel of a display apparatus according to some embodiments;

FIG. 4 is a cross-sectional view schematically showing a light-emitting diode and a pixel circuit electrically connected to the light-emitting diode, which are provided in a display apparatus according to some embodiments;

FIGS. 5 and 6 schematically show a plan view of a display apparatus according to some embodiments;

FIG. 7 schematically shows an enlarged plan view of a region A of FIG. 6, according to some embodiments;

FIG. 8 schematically shows a cross-sectional view of the display apparatus shown in FIG. 7 taken along a line I-I′ of FIG. 7, according to some embodiments;

FIG. 9 schematically shows an enlarged plan view of a region B of FIG. 8, according to some embodiments;

FIG. 10 schematically shows a cross-sectional view of the display apparatus shown in FIG. 9 taken along a line II-II′ of FIG. 9, according to some embodiments;

FIG. 11 schematically shows a plan view of a display apparatus according to some embodiments;

FIG. 12 schematically shows a plan view of a display apparatus according to some embodiments;

FIG. 13 schematically shows a cross-sectional view of the display apparatus shown in FIG. 12 taken along a line I-II′ of FIG. 12, according to some embodiments;

and

FIG. 14 schematically shows a plan view of a display apparatus according to some embodiments.

### DETAILED DESCRIPTION

Reference will now be made in detail to aspects of some embodiments, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, embodiments of the present disclosure will be described in more detail with reference to the accompanying drawings, and in the description with reference to the drawings, the same or corresponding components are indicated by the same reference numerals and redundant descriptions thereof are omitted.

In the following embodiments, it will be understood that although the terms “first,” “second,” etc. may be used herein to describe various components, these components should not be limited by these terms. These terms are only used to distinguish one component from another.

In the following embodiments, the expression of singularity in the present specification includes the expression of plurality unless clearly specified otherwise in context.

In the following embodiments, it will be further understood that the terms “comprises” and/or “comprising” used herein specify the presence of stated features or components, but do not preclude the presence or addition of one or more other features or components.

In the following embodiments, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed at the same time (or substantially at the same time) or performed in an order opposite to the described order.

In the present specification, the expression “A and/or B” represents A, B, or A and B. In addition, the expression “at least one of A and B” represents A, B, or A and B.

It will be understood that when a layer, region, or component is referred to as being “connected to” another layer, area, or component, it can be directly or indirectly connected to the other layer, region, or component. That is, for example, intervening layers, regions, or components may be present. For example, in the present specification, when a layer, region, or component is electrically connected to another layer, region, or component, the layers, regions, or components may not only be directly electrically connected, but may also be indirectly electrically connected via another layer, region, or component therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

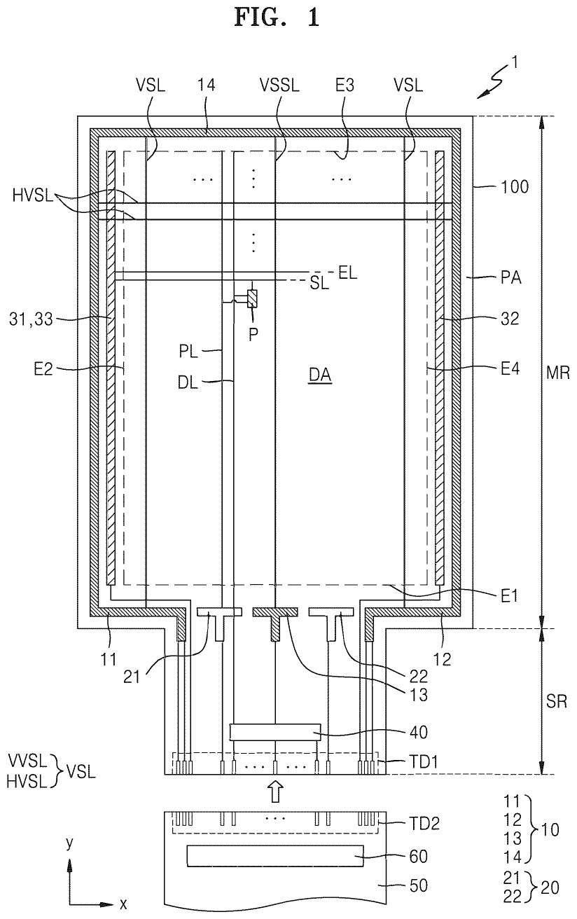

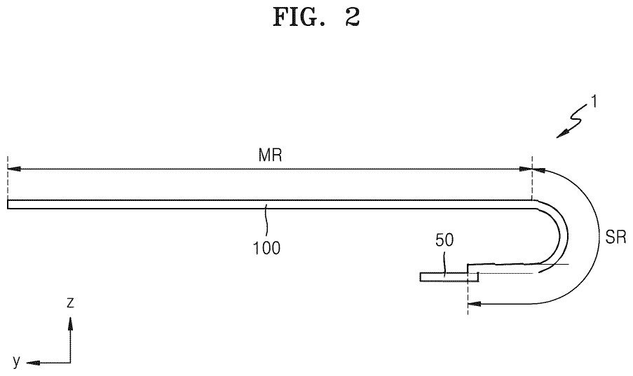

FIG. 1 is a plan view schematically showing a display apparatus according to some embodiments. FIG. 2 is a side view schematically showing the display apparatus shown in FIG. 1.

Referring to FIGS. 1 and 2, the display apparatus includes a display panel 1. The display apparatus may be any display apparatus including the display panel 1. For example, the display apparatus may be incorporated into an electronic device that may be any of various products, such as a smartphone, tablet PC, television, or billboard.

The display panel 1 includes a display region DA and a peripheral region PA outside (e.g., in a periphery or outside a footprint of) the display region DA. The display region DA is a portion that displays images, and a plurality of pixels P may be arranged in the display region DA. When viewed in a direction that is perpendicular (or substantially perpendicular) to a display surface of the display panel 1 (e.g., in a plan view), the display region DA may have various shapes, such as a circular, elliptical, or polygonal shape or the shape of a specific figure. FIG. 1 shows that the display region DA has a quadrangular shape, but according to some embodiments, the display region DA may have a quadrangular shape with rounded corners.

The peripheral region PA may be arranged outside (e.g., in a periphery or outside a footprint of) the display region DA. The peripheral region PA may entirely surround the display region DA. A portion (hereinafter, referred to as a protruding peripheral region) of the peripheral region PA may extend in a direction (−y direction) away from the display region DA. In other words, the display panel 1 may include a main region MR including the display region DA and a portion of the peripheral region PA surrounding the display region DA, and a sub-region SR extending from the main region MR in one direction, and the sub-region SR may correspond to the protruding peripheral region. The width of the sub-region SR (in an x direction) may be smaller than the width of the main region MR (in the x direction), and a portion of the sub-region SR may be bent as shown in FIG. 2. In a case where the display panel 1 is bent, as shown in FIG. 2, when viewing the display apparatus, the peripheral region PA, which is a non-display region, may be prevented from being visible, or even when visible, the area that is visible may be minimized or relatively reduced.

The shape of the display panel 1 may be the same (or substantially the same) as the shape of a substrate 100. For example, the substrate 100 may include the display region DA and the peripheral region PA. Alternatively, the substrate 100 may include the main region MR and the sub-region SR.

A pixel P is arranged in the display region DA and may emit red light, green light, or blue light. For example, the pixel P may emit light having a certain color by using a light-emitting diode that emits light. The light-emitting diode may be an organic light-emitting diode, an inorganic light-emitting diode, or a quantum dot light-emitting diode. Hereinafter, for convenience of explanation, a case where the light-emitting diode is an organic light-emitting diode is described.

The light-emitting diode may be connected to transistors connected to signal lines or voltage lines for controlling on/off and luminance of the light-emitting diode. In this regard, FIG. 1 shows a scan line SL, an emission control line EL, and a data line DL as the signal lines connected to the transistors, and shows a driving voltage line PL and a common voltage line VSL as the voltage lines. A common voltage supply unit 10, a driving voltage supply unit 20, first and second scan driving circuits 31 and 32, an emission control driving circuit 33, and a data driving circuit 40 may be arranged in the peripheral region PA.

The common voltage supply unit 10 may be arranged in the peripheral region PA. The common voltage supply unit 10 may include a first common voltage input unit 11, a second common voltage input unit 12, and a third common voltage input unit 13, which are arranged adjacent to a first edge E1 of the display region DA. The first common voltage input unit 11 and the second common voltage input unit 12 are spaced apart from each other, and the third common voltage input unit 13 may be located between the first common voltage input unit 11 and the second common voltage input unit 12. The third common voltage input unit 13 may be spaced apart from each of the first common voltage input unit 11 and the second common voltage input unit 12. The first common voltage input unit 11 and the second common voltage input unit 12 are respectively arranged at both ends of the first edge E1 of the display region DA, and the third common voltage input unit 13 may be arranged at the center of the first edge E1 of the display region DA. The disclosure has been described based on a case where the common voltage supply unit 10 includes the first common voltage input unit 11, the second common voltage input unit 12, and the third common voltage input unit 13, but the disclosure is not limited thereto, and according to some embodiments, the third common voltage input unit 13 is omitted, and thus, only the first common voltage input unit 11 and the second common voltage input unit 12 may be arranged.

The first common voltage input unit 11 and the second common voltage input unit 12 may be connected to each other by a body portion 14 extending along a second edge E2, a third edge E3, and a fourth edge E4 of the display region DA. In other words, the first common voltage input unit 11, the second common voltage input unit 12, and the body portion 14 may be integrally formed with one another as a single body.

The common voltage supply unit 10 may be electrically connected to vertical common voltage lines VVSL passing through the display region DA. Some of the vertical common voltage lines VVSL may extend from the first to third common voltage input units 11, 12, and 13 toward the display region DA. Any one of the vertical common voltage lines VVSL may cross the display region DA in a first direction (for example, y direction) to connect the third common voltage input unit 13 with a portion of the body portion 14, facing the third common voltage input unit 13. Another one of the vertical common voltage lines VVSL may cross the display region DA in the first direction (for example, y direction) to connect the first common voltage input unit 11 with a portion of the body portion 14, facing the first common voltage input unit 11. Similarly, another one of the vertical common voltage lines VVSL may cross the display region DA in the first direction to connect the second common voltage input unit 12 with a portion of the body portion 14, facing the second common voltage input unit 12. The vertical common voltage lines VVSL extending in the first direction may be electrically connected to a horizontal common voltage line HVSL extending in a second direction (for example, x direction) crossing the first direction.

In a case where the common voltage supply unit 10 includes the third common voltage input unit 13 arranged between the first and second common voltage input units 11 and 12, when the common voltage supply unit 10 apply the current, it is possible to lower current density and suppress heat generation.

The driving voltage supply unit 20 is arranged in the peripheral region PA and may be electrically connected to the driving voltage line PL crossing the display region DA in the first direction. According to some embodiments, the driving voltage supply unit 20 may include first and second driving voltage input units 21 and 22 respectively arranged at both sides of the third common voltage input unit 13 that is positioned therebetween.

The first and second scan driving circuits 31 and 32 are arranged in the peripheral region PA and may be electrically connected to the scan line SL. According to some embodiments, some of scan lines SL may be electrically connected to the first scan driving circuit 31, and the others may be connected to the second scan driving circuit 32. The first and second scan driving circuits 31 and 32 may be configured to generate scan signals, and the generated scan signals may be transmitted to a transistor electrically connected to a light-emitting diode via the scan line SL.

The emission control driving circuit 33 is located at a side of the first scan driving circuit 31, and an emission control signal may be transmitted to a transistor electrically connected to a light-emitting diode via the emission control line EL. FIG. 1 shows that the emission control driving circuit 33 is arranged only on one side of the display region DA, but like the first scan driving circuit 31 and the second scan driving circuit 32, the emission control driving circuit 33 may be arranged at either side of the display region DA.

The data driving circuit 40 may be arranged in the sub-region SR. The data driving circuit 40 may be configured to transmit a data signal to a transistor electrically connected to a light-emitting diode via the data line DL.

A first terminal portion TD1 may be located on only one side of the substrate 100, for example, at one end portion of the sub-region SR. A printed circuit board 50 may be attached onto the first terminal portion TD1. The printed circuit board 50 includes a second terminal portion TD2 electrically connected to the first terminal portion TD1, and a controller 60 may be located on the printed circuit board 50. Control signals of the controller 60 may be respectively provided to the first and second scan driving circuits 31 and 32, the emission control driving circuit 33, the data driving circuit 40, the driving voltage supply unit 20, and the common voltage supply unit 10 via the first and second terminal portions TD1 and TD2.

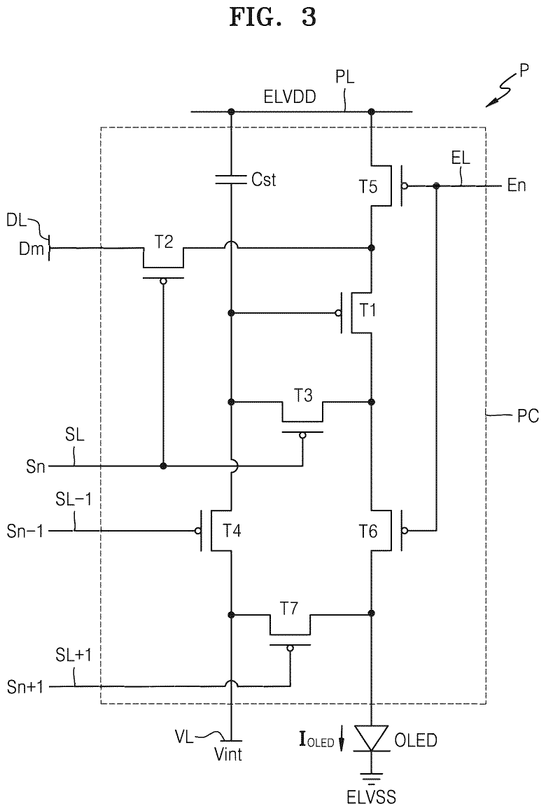

FIG. 3 is an equivalent circuit view schematically showing a pixel circuit electrically connected to a light-emitting diode corresponding to a pixel of a display apparatus according to some embodiments. Although FIG. 3 illustrates various components in a pixel circuit, embodiments according to the present disclosure are not limited thereto, and according to various embodiments, the pixel circuit may include additional components or fewer components without departing from the spirit and scope of embodiments according to the present disclosure.

Referring to FIG. 3, one pixel P may include a pixel circuit PC and an organic light-emitting diode OLED electrically connected to the pixel circuit PC.

For example, the pixel circuit PC includes first to seventh transistors T1 to T7 and a storage capacitor Cst, as shown in FIG. 3. The first to seventh transistors T1 to T7 and the storage capacitor Cst are connected to first to third scan lines SL, SL-1, and SL+1, which are respectively configured to transmit first to third scan signals Sn, Sn-1, and Sn+1, the data line DL configured to transmit a data voltage Dm, an emission control line EL configured to transmit an emission control signal En, a driving voltage line PL configured to transmit a driving voltage ELVDD, an initialization voltage line VL configured to transmit an initialization voltage Vint, and a common electrode to which a common voltage ELVSS is applied.

The first transistor T1 may be a driving transistor of which drain current size is determined according to a gate-source voltage, and the second to seventh transistors T2 to T7 may be switching transistors that are turned on/off according to a gate-source voltage, substantially a gate voltage. The first to seventh transistors T1 to T7 may be formed as thin-film transistors.

The first transistor T1 may be referred to as a driving transistor, the second transistor T2 may be referred to as a scan transistor, the third transistor T3 may be referred to as a compensation transistor, the fourth transistor T4 may be referred to as a gate initialization transistor, the fifth transistor T5 may be referred to as a first emission control transistor, the sixth transistor T6 may be referred to as a second emission control transistor, and the seventh transistor T7 may be referred to as an anode initialization transistor.

The storage capacitor Cst is connected between the driving voltage line PL and a gate of the driving transistor T1. The storage capacitor Cst may have an upper electrode CE2 connected to the driving voltage line PL, and a lower electrode CE1 connected to the gate of the driving transistor T1.

The driving transistor T1 may be configured to control the magnitude of a driving current IOLED flowing from the driving voltage line PL to the organic light-emitting diode OLED according to a gate-source voltage. The driving transistor T1 may have a source connected to the driving voltage line PL via the gate connected to the lower electrode CE1 of the storage capacitor Cst and the first emission control transistor T5, and may have a drain connected to the organic light-emitting diode OLED via the second emission control transistor T6.

The driving transistor T1 may be configured to output the driving current IOLED to the organic light-emitting diode OLED according to a gate-source voltage. The magnitude of the driving current IOLED is determined based on a difference between a gate-source voltage and a threshold voltage of the driving transistor T1. The organic light-emitting diode OLED may receive the driving current IOLED from the driving transistor T1, and may emit light with brightness according to the magnitude of the driving current IOLED.

The scan transistor T2 may be configured to transmit the data voltage Dm to the source of the driving transistor T1 in response to the first scan signal Sn. The scan transistor T2 may have a gate connected to the first scan line SL, a source connected to the data line DL, and a drain connected to the source of the driving transistor T1.

The compensation transistor T3 is connected in series between the drain and gate of the driving transistor T1, and is configured to connect the drain and gate of the driving transistor T1 to each other in response to the first scan signal Sn. The compensation transistor T3 may have a gate connected to the first scan line SL, a source connected to the drain of the driving transistor T1, and a drain connected to the gate of the driving transistor T1. FIG. 3 shows that the compensation transistor T3 is formed of one transistor, but the compensation transistor T3 may include two transistors connected in series.

The gate initialization transistor T4 is configured to apply the initialization voltage Vint to the gate of the driving transistor T1 in response to the second scan signal Sn-1. The gate initialization transistor T4 may have a gate connected to the second scan line SL-1, a source connected to the gate of the driving transistor T1, and a drain connected to the initialization voltage line VL. FIG. 3 shows that the gate initialization transistor T4 is formed of one transistor, but the gate initialization transistor T4 may include two transistors connected in series.

The anode initialization transistor T7 is configured to apply the initialization voltage Vint to an anode of the organic light-emitting diode OLED in response to the third scan signal Sn+1. The anode initialization transistor T7 may have a gate connected to the third scan line SL+1, a source connected to the anode of the organic light-emitting diode OLED, and a drain connected to the initialization voltage line VL. According to some embodiments, a signal applied to the anode initialization transistor T7 may be an output signal GB of a driving driver.

The first emission control transistor T5 may be configured to connect the driving voltage line PL with the source of the driving transistor T1 in response to the emission control signal En. The first emission control transistor T5 may have a gate connected to the emission control line EL, a source connected to the driving voltage line PL, and a drain connected to the source of the driving transistor T1.

The second emission control transistor T6 may connect the drain of the driving transistor T1 with the anode of the organic light-emitting diode OLED in response to the emission control signal En. The second emission control transistor T6 may have a gate connected to the emission control line EL, a source connected to the drain of the driving transistor T1, and a drain connected to the anode of the organic light-emitting diode OLED.

The second scan signal Sn-1 may be synchronized (or substantially synchronized) with the first scan signal Sn of the previous row. The third scan signal Sn+1 may be synchronized (or substantially synchronized) with the first scan signal Sn. According to some embodiments, the third scan signal Sn+1 may be synchronized (or substantially synchronized) with the first scan signal Sn of the next row.

According to some embodiments, each of the first to seventh transistors T1 to T7 may include a semiconductor layer including silicon. According to some embodiments, the first to seventh transistors T1 to T7 may include a semiconductor layer including a low-temperature polysilicon (LTPS). Polysilicon material has high electron mobility (at least 100 cm²/Vs), low energy consumption, and excellent reliability.

According to some embodiments, the semiconductor layers of the first to seventh transistors T1 to T7 may include oxides of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn). For example, each of the semiconductor layers may be an InSnZnO (ITZO) semiconductor layer, InGaZnO (IGZO) semiconductor layer, etc.

According to some embodiments, some semiconductor layers of the first to seventh transistors T1 to T7 may be formed of LTPS, some other semiconductor layers may be formed of oxide semiconductors (IGZO, etc.).

Hereinafter, a specific operation process of one pixel P of a display apparatus according to some embodiments is described in more detail. As shown in FIG. 3, it is assumed that each of the first to seventh transistors T1 to T7 is a p-type MOSFET.

First, when the emission control signal En at a high level is received, the first emission control transistor T5 and the second emission control transistor T6 are turned off, the driving transistor T1 stops outputting the driving current IOLED, and the organic light-emitting diode OLED stops emitting light.

Afterwards, during a gate initialization period in which the second scan signal Sn-1 at a low level is received, the gate initialization transistor T4 is turned on, and the initialization voltage Vint is applied to the gate of the driving transistor T1, that is, the lower electrode CE1 of the storage capacitor Cst. A difference (ELVDD-Vint) between the driving voltage ELVDD and the initialization voltage Vint is stored in the storage capacitor Cst.

Afterwards, during a data write period in which the first scan signal Sn at a low level is received, the scan transistor T2 and the compensation transistor T3 are turned on, and the data voltage Dm is received by the source of the driving transistor T1. The driving transistor T1 is diode-connected and forward biased by the compensation transistor T3. A gate voltage of the driving transistor T1 rises from the initialization voltage Vint. When the gate voltage of the driving transistor T1 becomes equal to a data compensation voltage (Dm−|Vth|) obtained by reducing a threshold voltage Vth of the driving transistor T1 from the data voltage Dm, the driving transistor T1 is turned off, and the gate voltage of the driving transistor T1 stops rising. Accordingly, a difference (ELVDD−Dm+|Vth|) between the driving voltage ELVDD and the data compensation voltage (Dm−|Vth|) is stored in the storage capacitor Cst.

In addition, during an anode initialization period in which the third scan signal Sn+1 at a low level is received, the anode initialization transistor T7 is turned on, and the initialization voltage Vint is applied to the anode of the organic light-emitting diode OLED. Although the pixel P receives the data voltage Dm corresponding to black gradation in the next frame by applying the initialization voltage Vint to the anode of the organic light-emitting diode OLED to completely prevent emission of the organic light-emitting diode OLED, a phenomenon in which the organic light-emitting diode OLED slightly emits light may be eliminated.

The first scan signal Sn and the third scan signal Sn+1 may be synchronized (or substantially synchronized), and in this case, the data write period and the anode initialization period may be the same period.

Afterwards, when the emission control signal En at a low level is received, the first emission control transistor T5 and the second emission control transistor T6 may be turned on, the driving transistor T1 may be configured to output the driving current IOLED corresponding to a voltage (ELVDD−Dm) obtained by reducing the threshold voltage (|Vth|) of the driving transistor T1 from the voltage stored in the storage capacitor Cst, that is, a source-gate voltage (ELVDD−Dm+|Vth|) of the driving transistor T1, and the organic light-emitting diode OLED may emit light with luminance corresponding to the magnitude of the driving current IOLED.

Meanwhile, FIG. 3 illustrates an example in which the pixel circuit PC includes seven transistors and one storage capacitor, but the disclosure is not limited thereto. For example, the pixel circuit PC may include at least two transistors and/or at least two storage capacitors. According to some embodiments, the pixel circuit PC may include two transistors and one storage capacitor.

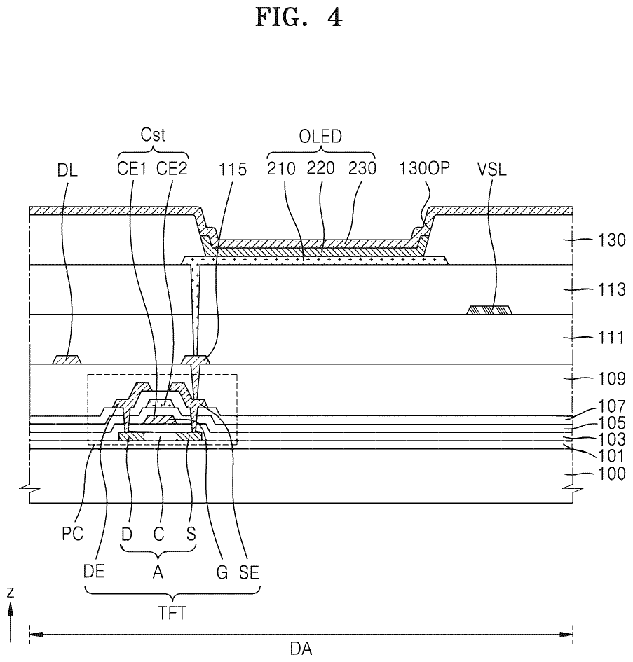

FIG. 4 is a cross-sectional view schematically showing a light-emitting diode and a pixel circuit electrically connected to the light-emitting diode, which are provided in a display apparatus according to some embodiments.

Referring to FIG. 4, the organic light-emitting diode OLED is arranged in the display region DA, and the organic light-emitting diode OLED may be electrically connected to the pixel circuit PC arranged between the substrate 100 and the organic light-emitting diode OLED in a direction (for example, z direction) perpendicular to the substrate 100.

The substrate 100 may include glass material or polymer resin. According to some embodiments, the substrate 100 may have a structure in which a base layer including polymer resin and a barrier layer including an inorganic insulating material such as silicon oxide or silicon nitride are alternately stacked. Polymer resin may include polyethersulfone, polyarylate, polyether imide, polyethylene naphthalate, polyethylene terephthalate, polyphenylene sulfide, polyimide, polycarbonate, cellulose triacetate, cellulose acetate propionate, etc.

Before the pixel circuit PC is formed, a buffer layer 101 may be formed on the substrate 100 to prevent or reduce penetration of contaminants or impurities into the pixel circuit PC. The buffer layer 101 may include an inorganic insulating material such as silicon nitride, silicon oxynitride, and silicon oxide, and may include a single-layer or multilayer structure including the inorganic insulating material.

The pixel circuit PC may include a thin-film transistor TFT and the storage capacitor Cst. The thin-film transistor TFT may be the driving transistor T1 as described above with reference to FIG. 3.

The thin-film transistor TFT may include a semiconductor layer A, a gate electrode G, a source electrode SE, and a drain electrode DE.

The semiconductor layer A may be located on the buffer layer 101. The semiconductor layer A may include polysilicon. Alternatively, the semiconductor layer A may include amorphous silicon, an oxide semiconductor, an organic semiconductor, etc. According to some embodiments, the semiconductor layer A may include a channel region C, and a source region S and a drain region D respectively arranged at both sides of the channel region C.

The gate electrode G may overlap the channel region C of the semiconductor layer A. The gate electrode G may include a low-resistance metal material.

A first inorganic insulating layer 103 may be arranged between the semiconductor layer A and the gate electrode G. The first inorganic insulating layer 103 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second inorganic insulating layer 105 may cover the gate electrode G. Similar to the first inorganic insulating layer 103, the second inorganic insulating layer 105 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The upper electrode CE2 of the storage capacitor Cst may be located above the second inorganic insulating layer 105. According to some embodiments, the upper electrode CE2 may overlap the gate electrode G. At this time, the gate electrode G and the upper electrode CE2, overlapping each other with the second inorganic insulating layer 105 therebetween, may form the storage capacitor Cst. In other words, the gate electrode G may function as the lower electrode CE1 of the storage capacitor Cst. As such, the storage capacitor Cst and the thin-film transistor TFT may overlap each other. According to some embodiments, the storage capacitor Cst and the thin-film transistor TFT may not overlap each other.

A third inorganic insulating layer 107 may cover the upper electrode CE2. The third inorganic insulating layer 107 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third inorganic insulating layer 107 may be a single layer or a multilayer, including the above-described inorganic insulating material.

Each of the source electrode SE and the drain electrode DE may be located on the third inorganic insulating layer 107. At least one of the source electrode SE or the drain electrode DE may include a material with excellent conductivity. At least one of the source electrode SE or the drain electrode DE may include a conductive material including molybdenum (Mo), aluminum (AI), copper (Cu), or titanium (Ti), and may be provided as a multilayer or a single layer, including the above material. According to some embodiments, at least one of the source electrode SE or the drain electrode DE may have a multilayer structure of Ti/Al/Ti.

A first organic insulating layer 109 may be located on the third inorganic insulating layer 107. The first organic insulating layer 109 may be located on the source electrode SE and the drain electrode DE. The first organic insulating layer 109 may include an organic material. The first organic insulating layer 109 may include an organic insulating material, such as a general purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

The data line DL may be located on the first organic insulating layer 109. The data line DL may include aluminum (AI), copper (Cu), and/or titanium (Ti), and may be formed as a single layer or a multilayer, including the above-described material. For example, the data line DL may have a three-layer structure of a titanium layer/aluminum layer/titanium layer.

A second organic insulating layer 111 may be located on the data line DL. The second organic insulating layer 111 may include an organic material. The second organic insulating layer 111 may include an organic insulating material, such as a general purpose polymer, such as PMMA or PS, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

A common voltage line may be located on the second organic insulating layer 111. For example, a horizontal common voltage line and a vertical common voltage line may be located on the second organic insulating layer 111. The horizontal common voltage line and the vertical common voltage line may be arranged in a same layer and may include a same material.

A third organic insulating layer 113 may be located on the common voltage line VSL. The third organic insulating layer 113 may include an organic material. The third organic insulating layer 113 may include an organic insulating material, such as a general purpose polymer, such as PMMA or PS, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

A light-emitting diode, for example, the organic light-emitting diode OLED, may be located on the third organic insulating layer 113. The organic light-emitting diode OLED may emit, for example, red, green, or blue light, or may emit red, green, blue, or white light. The organic light-emitting diode OLED may include a pixel electrode 210, an emission layer 220, and an opposite electrode 230.

The pixel electrode 210 may be located on the third organic insulating layer 113. The pixel electrode 210 may be electrically connected to the thin-film transistor TFT. For example, the pixel electrode 210 may be connected to a lower conductive layer 115 via contact holes in the third organic insulating layer 113 and the second organic insulating layer 111, and the lower conductive layer 115 may be connected to the thin-film transistor TFT via a contact hole in the first organic insulating layer 109. The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 210 may include a reflective film including silver (Ag), magnesium (Mg), aluminum (AI), platinum (Pt), palladium (Pd), gold (Au), nickel (Ni), neodymium (Nd), iridium (Ir), chromium (Cr), or a compound thereof. According to some embodiments, the pixel electrode 210 may further include a layer including ITO, IZO, ZnO, or In₂O₃ above/below the above-described reflective film.

A pixel-defining layer 130 having an opening 130OP exposing a central portion of the pixel electrode 210 may be located on the pixel electrode 210. The pixel-defining layer 130 may include an organic insulating material and/or an inorganic insulating material. The opening in the pixel-defining layer 130 may define an emission region where light from the organic light-emitting diode OLED is emitted.

The emission layer 220 may be arranged in the opening 130OP in the pixel-defining layer 130. The emission layer 220 may include a polymer or low-molecular-weight organic material that emits light of a certain color. According to some embodiments, a first functional layer and a second functional layer may be located above/below the emission layer 220. The first functional layer may include, for example, a hole transport layer (HTL) or may include a hole transport layer and a hole injection layer (HIL). The second functional layer is a component located above the emission layer 220 and is optional. The second functional layer may include an electron transport layer (ETL) and/or an electron injection layer (EIL). The first functional layer and/or the second functional layer may be a common layer formed to entirely cover the substrate 100, like the opposite electrode 230 described below.

The opposite electrode 230 may be located on the emission layer 220. The opposite electrode 230 may entirely cover the substrate 100 in the display region DA. The opposite electrode 230 may include a conductive material having a low work function. For example, the opposite electrode 230 may include a (semi) transparent layer including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer including ITO, IZO, ZnO, or In₂O₃ on the (semi) transparent layer including the above-described material.

According to some embodiments, an encapsulation layer may be located on the organic light-emitting diode OLED. The encapsulation layer may include at least one inorganic encapsulation layer and at least one organic encapsulation layer, covering the organic light-emitting diode OLED. According to some embodiments, at least one inorganic encapsulation layer and at least one organic encapsulation layer may be alternately stacked. An inorganic encapsulation layer may include at least one inorganic material among aluminum oxide (Al₂O₃), titanium oxide (TiO₂), tantalum oxide (Ta₂O₅), zinc oxide (ZnO), silicon oxide (SiO₂), silicon nitride (SiNₓ), and silicon oxynitride (SiON). An organic encapsulation layer may include a polymer-based material. The polymer-based material may include acrylic resin, epoxy-based resin, polyimide, and polyethylene. According to some embodiments, the organic encapsulation layer may include acrylate.

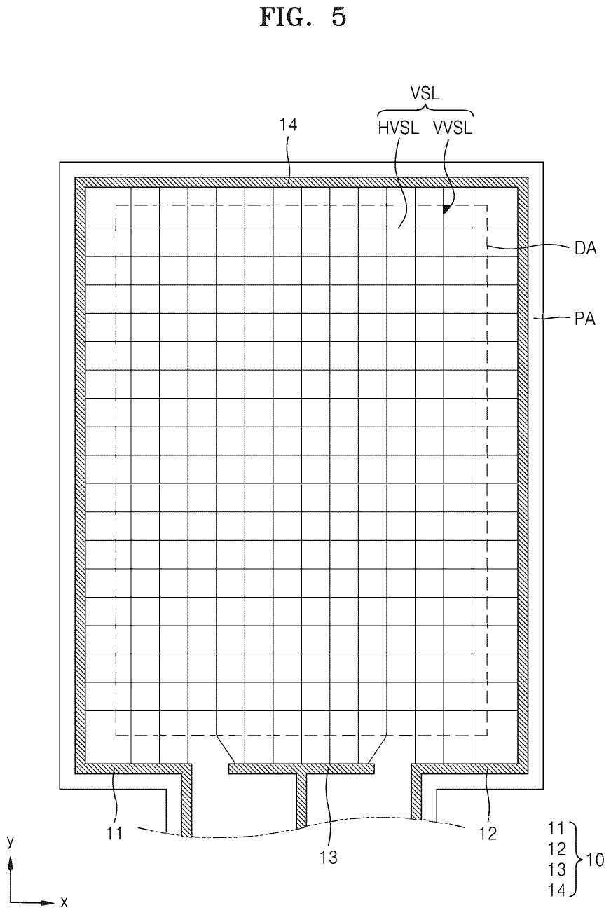

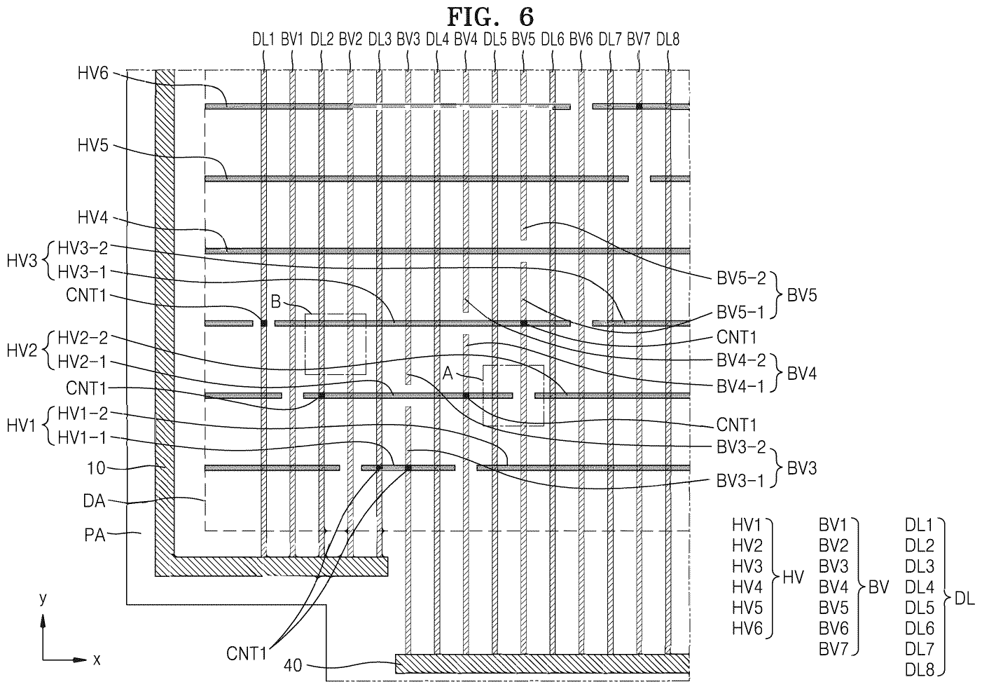

FIGS. 5 and 6 schematically show a plan view of a display apparatus according to some embodiments. For example, FIG. 5 is a plan view schematically showing the arrangement of common voltage lines in a display apparatus, and FIG. 6 is a plan view schematically showing the arrangement of data lines, horizontal connection lines, and vertical connection lines.

Referring to FIG. 5, the common voltage line VSL may include a horizontal common voltage line HVSL and a vertical common voltage line VVSL. Horizontal common voltage lines HVSL and vertical common voltage lines VVSL may be arranged in a display region. The horizontal common voltage line HVSL may extend in a first direction (for example, x direction or −x direction), and a plurality of horizontal common voltage lines HVSL may be arranged in a second direction (for example, y direction or −y direction). The vertical common voltage line VVSL may extend in the second direction (for example, y direction or −y direction), and a plurality of vertical common voltage lines VVSL may be arranged in the first direction (for example, x direction or −x direction). The plurality of horizontal common voltage lines HVSL and the plurality of vertical common voltage lines VVSL may be integrally formed with each other as a single body and may be arranged to form a mesh shape.

The horizontal common voltage lines HVSL and the vertical common voltage lines VVSL may be electrically connected to the common voltage supply unit 10 to supply a common voltage to a pixel arranged in the display region DA. The horizontal common voltage lines HVSL may be electrically connected to the common voltage supply unit arranged to extend in the second direction (for example, y direction or −y direction) in the peripheral region PA. In addition, the vertical common voltage lines VVSL may be electrically connected to the common voltage supply unit 10 arranged to extend in the first direction (for example, x direction or −x direction) in the peripheral region PA. For example, the vertical common voltage lines VVSL may be electrically connected to the first common voltage input unit 11, the second common voltage input unit 12, the third common voltage input unit 13, and the body portion 14 of the common voltage supply unit 10.

Referring to FIG. 6, data lines DL may be arranged in the display region DA and may extend in the second direction (for example, y direction or −y direction). A plurality of data lines DL may be arranged in the first direction (for example, x direction or −x direction). Vertical connection lines BV may be arranged in the display region DA and may extend in the second direction (for example, y direction or −y direction). A plurality of vertical connection lines BV may be arranged in the first direction (for example, x direction or −x direction). Horizontal connection lines HV may be arranged in the display region DA and may extend in the first direction (for example, x direction or −x direction). A plurality of horizontal connection lines HV may be arranged in the second direction (for example, y direction or −y direction).

The plurality of data lines DL may be configured to receive a data signal from the data driving circuit 40 and transmit the data signal to a transistor electrically connected to a light-emitting diode. The data lines DL arranged in a central portion of the display region DA may be directly electrically connected to the data driving circuit 40 to receive a data signal. However, like first to third data lines DL1, DL2, and DL3, when the data lines DL arranged at both sides of the display region DA are directly electrically connected to the data driving circuit 40, the area of the peripheral region PA may be increased. Therefore, like the first to third data lines DL1, DL2, and DL3, the data lines DL arranged at both sides of the display region DA may be electrically connected to the data driving circuit 40 via the horizontal connection lines HV and the vertical connection lines BV to increase the proportion of the display region DA in the display apparatus.

For example, the first data line DL1 may be electrically connected to the data driving circuit 40 via a fifth-1 vertical connection line BV5-1 and a third-1 horizontal connection line HV3-1 to receive a data signal. Because the fifth-1 vertical connection line BV5-1 and the third-1 horizontal connection line HV3-1 are arranged in different layers, the fifth-1 vertical connection line BV5-1 and the third-1 horizontal connection line HV3-1 may be electrically connected to each other via a first contact hole CNT1. The second data line DL2 may be electrically connected to the data driving circuit 40 via a fourth-1 vertical connection line BV4-1 and a second-1 horizontal connection line HV2-1 to receive a data signal. Because the fourth-1 vertical connection line BV4-1 and the second-1 horizontal connection line HV2-1 are arranged in different layers, the fourth-1 vertical connection line BV4-1 and the second-1 horizontal connection line HV2-1 may be electrically connected to each other via the first contact hole CNT1. The third data line DL3 may be electrically connected to the data driving circuit 40 via a third-1 vertical connection line BV3-1 and a first-1 horizontal connection line HV1-1 to receive a data signal. Because the third-1 vertical connection line BV3-1 and the first-1 horizontal connection line HV1-1 are arranged in different layers, the third-1 vertical connection line BV3-1 and the first-1 horizontal connection line HV1-1 may be electrically connected to each other via the first contact hole CNT1.

Some of the plurality of vertical connection lines BV are not electrically connected to the data driving circuit 40, and thus, a data signal is not applied to them. For example, a first vertical connection line BV1, a second vertical connection line BV2, a third-2 vertical connection line BV3-2, a fourth-2 vertical connection line BV4-2, and a fifth-2 vertical connection line BV5-2 are not electrically connected to the data driving circuit 40, and thus, a data signal may not be applied to them. The vertical connection lines BV (for example, the first vertical connection line BV1, the second vertical connection line BV2, the third-2 vertical connection line BV3-2, the fourth-2 vertical connection line BV4-2, and the fifth-2 vertical connection line BV5-2) to which a data signal is not applied may be electrically connected to the common voltage supply unit 10 arranged in the peripheral region PA to apply a common voltage to pixel circuits PC arranged in the display region DA. At least some of the vertical connection lines BV arranged in the display region DA may be additionally electrically connected to the common voltage supply unit 10 to apply a common voltage to the pixel circuits PC, and thus, voltage drop (IR drop) of the display apparatus may be solved, and the reliability and quality of the display apparatus may be relatively improved.

Some of the plurality of horizontal connection lines HV are not electrically connected to the data driving circuit 40, and thus, a data signal is not applied to them. For example, a first-2 horizontal connection line HV1-2, a second-2 horizontal connection line HV2-2, a third-2 horizontal connection line HV3-2, a fourth horizontal connection line HV4, and a fifth horizontal connection line HV5 are not electrically connected to the data driving circuit 40, and thus, a data signal may not be applied to them. The horizontal connection lines HV (for example, the first-2 horizontal connection line HV1-2, the second-2 horizontal connection line HV2-2, the third-2 horizontal connection line HV3-2, the fourth horizontal connection line HV4, and the fifth horizontal connection line HV5) to which a data signal is not applied may be electrically connected to the common voltage supply unit 10 arranged in the peripheral region PA to apply a common voltage to the pixel circuits PC arranged in the display region DA. At least some of the horizontal connection lines HV arranged in the display region DA may be additionally electrically connected to the common voltage supply unit 10 to apply a common voltage to the pixel circuits PC, and thus, voltage drop (IR drop) in the pixel circuits PC may be solved, and the quality and reliability of the display apparatus may be relatively improved.

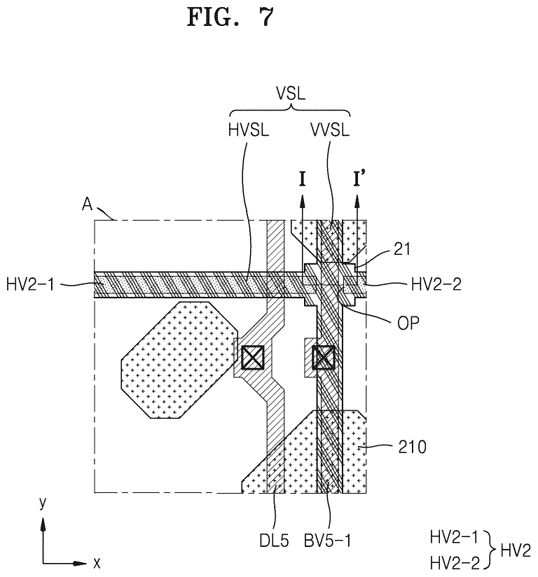

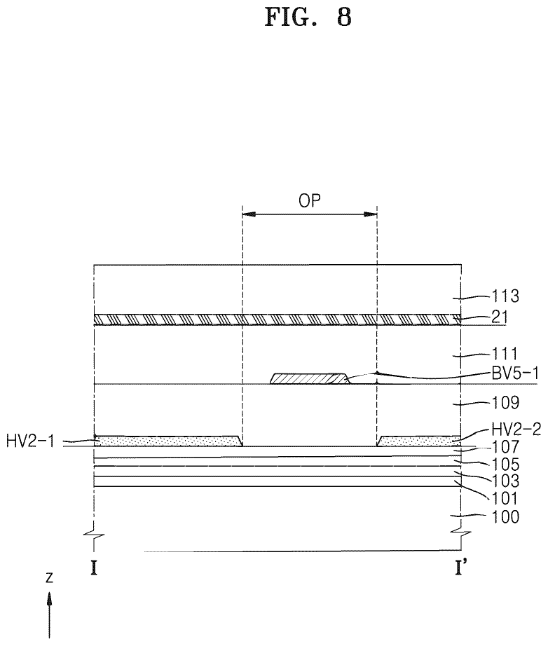

FIG. 7 schematically shows an enlarged plan view of a region A of FIG. 6, according to some embodiments. FIG. 8 schematically shows a cross-sectional view of the display apparatus shown in FIG. 7 taken along a line I-I′ of FIG. 7, according to some embodiments.

Referring to FIGS. 7 and 8, a second horizontal connection line HV2 may include the second-1 horizontal connection line HV2-1 and the second-2 horizontal connection line HV2-2. The second-1 horizontal connection line HV2-1 and the second-2 horizontal connection line HV2-2 may extend in the first direction (for example, x direction or −x direction). The second-1 horizontal connection line HV2-1 and the second-2 horizontal connection line HV2-2 may be spaced apart from each other in the first direction (for example, x direction or −x direction) with an opening OP in the second horizontal connection line HV2 therebetween.

A fifth data line DL5 and the fifth-1 vertical connection line BV5-1 may be located on the second horizontal connection line HV2. The fifth data line DL5 and the fifth-1 vertical connection line BV5-1 may be arranged to extend in the second direction (for example, y direction or −y direction), and the fifth data line DL5 and the fifth-1 vertical connection line BV5-1 may be arranged in the first direction (for example, x direction or −x direction). The fifth-1 vertical connection line BV5-1 may be arranged to pass through the opening OP in the second horizontal connection line HV2. In addition, the fifth data line DL5 and the fifth-1 vertical connection line BV5-1 may be arranged in a same layer and may include a same material.

The common voltage line VSL may be located on the fifth data line DL5 and the fifth-1 vertical connection line BV5-1. The common voltage line VSL may include the horizontal common voltage line HVSL and the vertical common voltage line VVSL. The horizontal common voltage line HVSL may extend in the first direction (for example, x direction or −x direction), and the vertical common voltage line VVSL may extend in the second direction (for example, y direction or −y direction). The horizontal common voltage line HVSL and the vertical common voltage line VVSL may be integrally formed with each other as a single body. The horizontal common voltage line HVSL and the vertical common voltage line VVSL may be arranged in a same layer and may include a same material. The pixel electrode 210 may be located on the common voltage line VSL.

According to some embodiments, the common voltage line VSL may be arranged to cover the opening OP in the horizontal common voltage line HVSL. On other words, the common voltage line VSL may be arranged to overlap the opening OP in the horizontal common voltage line HVSL. The common voltage line VSL may include a first shielding pattern 21. The first shielding pattern 21 of the common voltage line VSL may be arranged to cover the opening OP in the horizontal common voltage line HVSL. The horizontal common voltage line HVSL, the vertical common voltage line VVSL, and the first shielding pattern 21 may be integrally formed with one another as a single body. The horizontal common voltage line HVSL, the vertical common voltage line VVSL, and the first shielding pattern 21 may be arranged in a same layer and may include a same material.

When the pixel electrode 210 is arranged to cover the opening OP in the horizontal common voltage line HVSL to prevent or reduce visibility of the opening OP in the horizontal common voltage line HVSL from outside the display apparatus, the pixel electrode 210 is provided asymmetrically such that the reflectance with respect to external light may increase, and the reliability and quality of the display apparatus may deteriorate. According to some embodiments, the first shielding pattern 21 of the common voltage line VSL, rather than the pixel electrode 210, may be arranged to cover the opening OP in the horizontal common voltage line HVSL, and thus, the pixel electrode 210 is provided asymmetrically such that the reflectance with respect to external light may be prevented from increasing, and the reliability and quality of the display apparatus may be relatively improved.

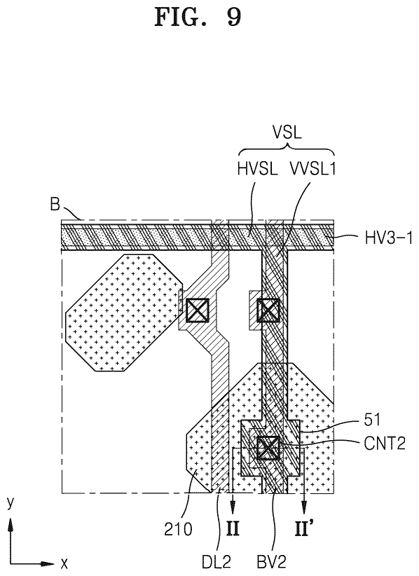

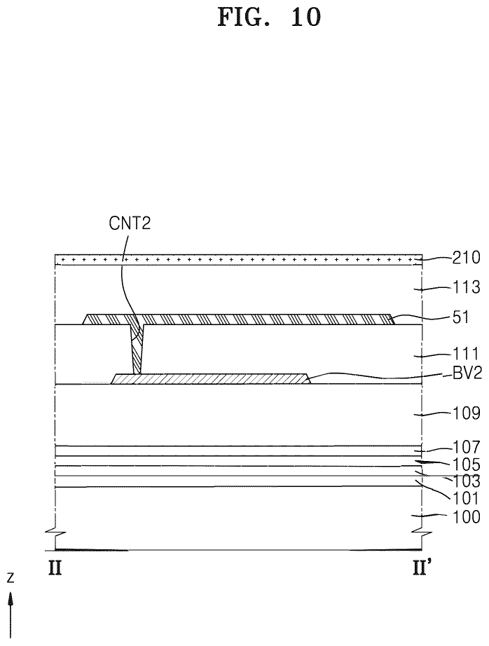

FIG. 9 schematically shows an enlarged plan view of a region B of FIG. 8, according to some embodiments. FIG. 10 schematically shows a cross-sectional view of the display apparatus shown in FIG. 9 taken along a line II-II′ of FIG. 9, according to some embodiments.

Referring to FIGS. 9 and 10, the third-1 horizontal connection line HV3-1 may extend in the first direction (for example, x direction or −x direction). The second data line DL2 and the second vertical connection line BV2 may be located on the third-horizontal connection line HV3-1. The second data line DL2 and the second vertical connection line BV2 may extend in the second direction (for example, y direction or −y direction). The second data line DL2 and the second vertical connection line BV2 may be arranged in the first direction (for example, x direction or −x direction). The second data line DL2 and the second vertical connection line BV2 may be arranged in a same layer and may include a same material. The second vertical connection line BV2 may be electrically connected to the common voltage supply unit 10 (see FIG. 1) to apply a common voltage to the pixel circuit PC (see FIG. 4) arranged in the display region DA (see FIG. 1).

The common voltage line VSL may be located on the second data line DL2 and the second vertical connection line BV2. The horizontal common voltage line HVSL and a first vertical common voltage line VVSL1 may be located on the second data line DL2 and the second vertical connection line BV2. The horizontal common voltage line HVSL may extend in the first direction (for example, x direction or −x direction), and the first vertical common voltage line VVSL1 may extend in the second direction (for example, y direction or −y direction). The horizontal common voltage line HVSL and the first vertical common voltage line VVSL1 may be integrally formed with each other as a single body. The horizontal common voltage line HVSL and the first vertical common voltage line VVSL1 may be arranged in a same layer and may include a same material.

The first vertical common voltage line VVSL1 may include a first conductive pattern 51. The first vertical common voltage line VVSL1 and the first conductive pattern 51 may be integrally formed with each other as a single body. The first vertical common voltage line VVSL1 and the second vertical connection line BV2 may be electrically connected to each other via a second contact hole CNT2 in the first conductive pattern 51. The second vertical connection line BV2 and the first vertical common voltage line VVSL1 are electrically connected to the common voltage supply unit 10 (see FIG. 1) to transmit a common voltage to the pixel circuit PC (see FIG. 4) arranged in the display region, and thus, the second vertical connection line BV2 and the first vertical common voltage line VVSL1 may be electrically connected to each other. The first vertical common voltage line VVSL1 and the second vertical connection line BV2, to which a common voltage is applied, are electrically connected to each other via the second contact hole CNT2 arranged in the first conductive pattern 51 of the first vertical common voltage line VVSL1, and thus, voltage drop within a region of the display panel may be relatively improved, and heat generated from the display panel may be dispersed to relatively improve the reliability and quality of the display apparatus.

The organic light-emitting diode OLED may be located on the common voltage line VSL. The organic light-emitting diode OLED may include the pixel electrode 210, the emission layer 220, and the opposite electrode 230. The pixel electrode 210 may be arranged to cover the first conductive pattern 51 of the first vertical common voltage line VVSL1 and the second contact hole CNT2. The pixel electrode 210 may be arranged to cover the second contact hole CNT2 in the first conductive pattern 51, and thus, visibility of the second contact hole CNT2 from outside the display apparatus may be prevented or reduced, and the reliability and quality of the display apparatus may be relatively improved.

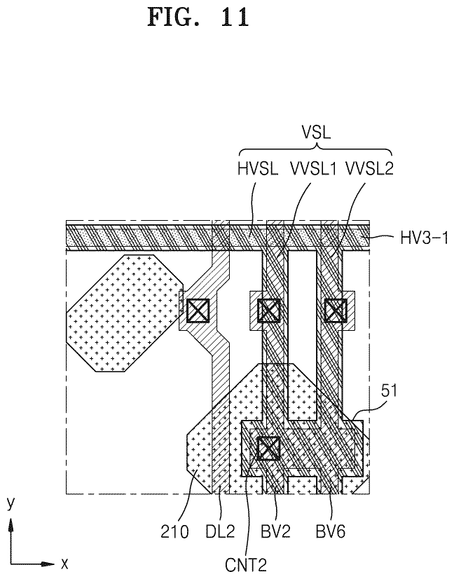

FIG. 11 schematically shows a plan view of a display apparatus according to some embodiments. Among the components shown in FIG. 11, the second data line DL2, the second vertical connection line BV2, the horizontal common voltage line HVSL, the first vertical common voltage line VVSL1, and the pixel electrode 210 are as shown in FIG. 9.

Referring to FIG. 11, a sixth vertical connection line BV6 may be spaced apart from the second vertical connection line BV2 in the first direction (for example, x direction or −x direction). The second vertical connection line BV2 and the sixth vertical connection line BV6 may extend in the second direction (for example, y direction or −y direction). The second vertical connection line BV2 and the sixth vertical connection line BV6 may be electrically connected to the common voltage supply unit 10 (see FIG. 1) to apply a common voltage to the pixel circuit PC (see FIG. 4) arranged in the display region DA (see FIG. 1).

A second vertical common voltage line VVSL2 may be spaced apart from the first vertical common voltage line VVSL1 in the first direction (for example, x direction or −x direction). The first vertical common voltage line VVSL1 and the second vertical common voltage line VVSL2 may extend in the second direction (for example, y direction or −y direction). The first vertical common voltage line VVSL1 and the second vertical common voltage line VVSL2 may be electrically connected to the common voltage supply unit 10 to apply a common voltage to the pixel circuit PC arranged in the display region DA.

The first vertical common voltage line VVSL1 and the second vertical common voltage line VVSL2 may include the first conductive pattern 51. The first vertical common voltage line VVSL1, the second vertical common voltage line VVSL2, and the first conductive pattern 51 may be integrally formed with one another as a single body. The second vertical common voltage line VVSL2 and the second vertical connection line BV2 may be electrically connected to each other via the second contact hole CNT2 in the first conductive pattern 51 included in the first vertical common voltage line VVSL1 and the second vertical common voltage line VVSL2.

The first vertical common voltage line VVSL1 and the second vertical common voltage line VVSL2 are electrically connected to the second vertical connection line BV2 and the sixth vertical connection line BV6, to which a common voltage is applied, via the second contact hole CNT2, and thus, voltage drop (IR drop) within a region of the display panel may be relatively improved, and heat generated from the display panel may be dispersed to relatively improve the reliability and quality of the display apparatus.

The pixel electrode 210 of the organic light-emitting diode OLED may be located on the common voltage line VSL. The pixel electrode 210 may be arranged to cover the first conductive pattern 51 included in the first vertical common voltage line VVSL1 and the second vertical common voltage line VVSL2, and the second contact hole CNT2. The pixel electrode 210 may be arranged to cover the second contact hole CNT2 in the first conductive pattern 51, and thus, visibility of the second contact hole CNT2 from outside the display apparatus may be prevented or reduced, and the quality and reliability of the display apparatus may be relatively improved.

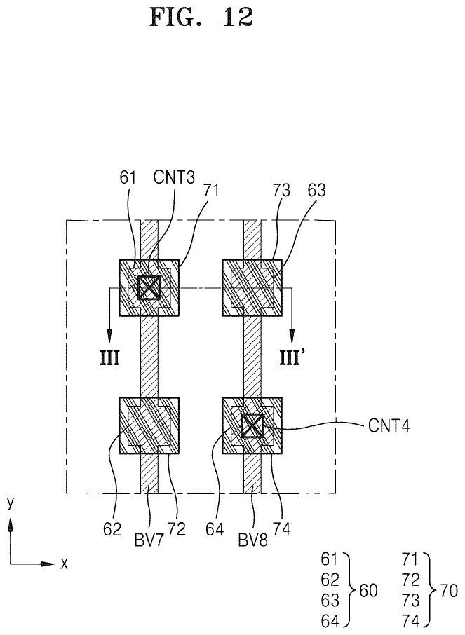

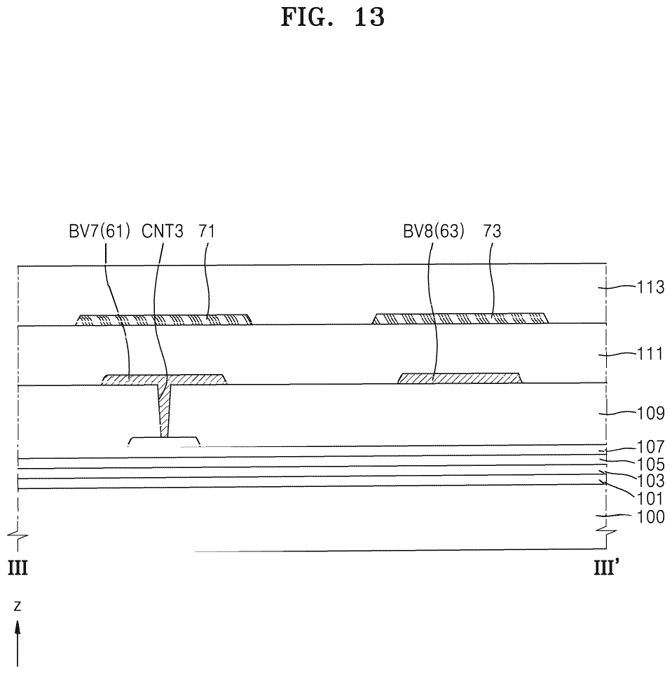

FIG. 12 schematically shows a plan view of a display apparatus according to some embodiments. FIG. 13 schematically shows a cross-sectional view of the display apparatus shown in FIG. 12 taken along a line I-II′ of FIG. 12, according to some embodiments.

Referring to FIGS. 12 and 13, a seventh vertical connection line BV7 and an eighth vertical connection line BV8 may extend in the second direction (for example, y direction or −y direction). The seventh vertical connection line BV7 and the eighth vertical connection line BV8 may be arranged in the first direction (for example, x direction or −x direction). The seventh vertical connection line BV7 and the eighth vertical connection line BV8 may be arranged in a same layer and may include a same material. The seventh vertical connection line BV7 may be electrically connected to the driving voltage supply unit 20 to apply a driving voltage to the pixel circuit PC arranged in the display region DA. The eighth vertical connection line BV8 may be electrically connected to the common voltage supply unit 10 to apply a common voltage to the pixel circuit PC arranged in the display region DA.

The seventh vertical connection line BV7 may include a first conductive pattern 61 and a second conductive pattern 62. The first conductive pattern 61 and the second conductive pattern 62 may be integrally formed with the seventh vertical connection line BV7. The eighth vertical connection line BV8 may include a third conductive pattern 63 and a fourth conductive pattern 64. The third conductive pattern 63 and the fourth conductive pattern 64 may be integrally formed with the eighth vertical connection line BV8. The first conductive pattern 61 of the seventh vertical connection line BV7 and the third conductive pattern 63 of the eighth vertical connection line BV8 may be spaced apart from each other in the first direction (for example, x direction or −x direction). The second conductive pattern 62 of the seventh vertical connection line BV7 and the fourth conductive pattern 64 of the eighth vertical connection line BV8 may be spaced apart from each other in the first direction (for example, x direction or −x direction).

A third contact hole CNT3 may be arranged in the first conductive pattern 61 of the seventh vertical connection line BV7. The seventh vertical connection line BV7 may be electrically connected to an electrode located under the seventh vertical connection line BV7 via the third contact hole CNT3. In other words, a driving voltage applied to the seventh vertical connection line BV7 may be applied to the pixel circuit PC via the third contact hole CNT3. A fourth contact hole CNT4 may be arranged in the fourth conductive pattern 64 of the eighth vertical connection line BV8. The eighth vertical connection line BV8 may be electrically connected to an electrode located under the eighth vertical connection line BV8 via the fourth contact hole CNT4. In other words, a common voltage applied to the eighth vertical connection line BV8 may be applied to the pixel circuit PC via the fourth contact hole CNT4.

A plurality of shielding patterns 70 may be located on the seventh vertical connection line BV7 and the eighth vertical connection line BV8. The plurality of shielding patterns 70 may include a first shielding pattern 71, a second shielding pattern 72, a third shielding pattern 73, and a fourth shielding pattern 74. The first shielding pattern 71, the second shielding pattern 72, the third shielding pattern 73, and the fourth shielding pattern 74 may be respectively arranged to cover the first conductive pattern 61, the second conductive pattern 62, the third conductive pattern 63, and the fourth conductive pattern 64. The first shielding pattern 71, the second shielding pattern 72, the third shielding pattern 73, and the fourth shielding pattern 74 may be respectively arranged to cover the first conductive pattern 61, the second conductive pattern 62, the third conductive pattern 63, and the fourth conductive pattern 64, and thus, it may be possible to prevent or reduce differences in quality and reliability of the display apparatus depending on the position of the third contact hole CNT3 in the seventh vertical connection line BV7 and the position of the fourth contact hole CNT4 in the eighth vertical connection line BV8. For example, the first to fourth shielding patterns 71, 72, 73, and 74 may be respectively arranged to cover the first to fourth conductive patterns 61, 62, 63, and 64, and thus, it is possible to minimize a difference in the degree of signal application and a difference in positions where a contact hole is visible from outside the display apparatus, depending on the position of the third contact hole CNT3 in the seventh vertical connection line BV7 and the position of the fourth contact hole CNT4 in the eighth vertical connection line BV8.

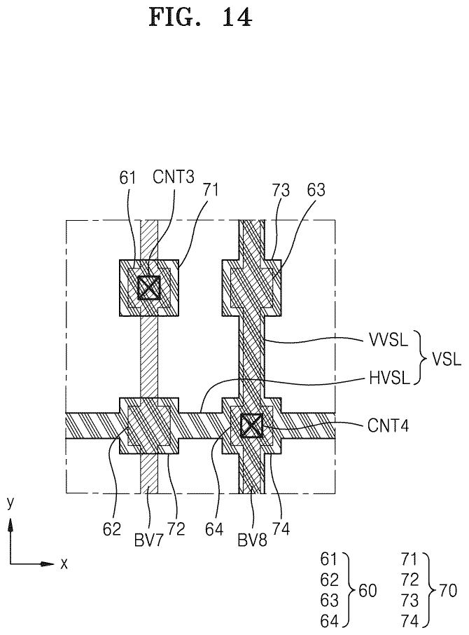

FIG. 14 schematically shows a plan view of a display apparatus according to some embodiments. The first to fourth conductive patterns 61, 62, 63, and 64, the first to fourth shielding patterns 71, 72, 73, and 74, the seventh vertical connection line BV7, the eighth vertical connection line BV8, the third contact hole CNT3, and the fourth contact hole CNT4, which are shown in FIG. 14, are the same as the components shown in FIG. 13.

Referring to FIG. 14, the plurality of shielding patterns 70 and the common voltage line VSL may be arranged in a same layer and may include a same material. The second shielding pattern 72 and the fourth shielding pattern 74 may be integrally formed with the horizontal common voltage line HVSL. The third shielding pattern 73 and the fourth shielding pattern 74 may be integrally formed with the vertical common voltage line VVSL. The horizontal common voltage line HVSL and the vertical common voltage line VVSL may also be integrally formed with each other as a single body.

The horizontal common voltage line HVSL or the vertical common voltage line VVSL may be electrically connected to the eighth vertical connection line BV8. The horizontal common voltage line HVSL or the vertical common voltage line VVSL may be electrically connected to the eighth vertical connection line BV8 to which a common voltage is applied, and thus, voltage drop (IR drop) within a region of the display panel may be relatively improved, and heat generated from the display panel may be dispersed to relatively improve the reliability and quality of the display apparatus.

According to some embodiments, common voltage lines VSL that apply a common voltage to the pixel circuit PC arranged in the display region DA are arranged to cover the opening OP in the horizontal connection line HV or a conductive pattern of the vertical connection line BV, and thus, the reflectance of the display apparatus with respect to external light may be reduced, or differences in reliability across different regions of the display apparatus depending on the position of a contact hole between wires may be prevented or reduced, and when the vertical connection line BV is electrically connected to the common voltage supply unit 10 to apply a common voltage to the pixel circuit PC, voltage drop within the display panel may be prevented or reduced by electrically connecting the vertical connection line BV to the common voltage line VSL, and the quality and reliability of the display apparatus may be relatively improved.

According to some embodiments as described above, a display apparatus with relatively improved reliability and quality may be implemented. However, the scope embodiments according to the present disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate comprising a display region and a peripheral region outside the display region;
a common voltage supply unit in the peripheral region and surrounding at least a portion of the display region;
a common voltage line electrically connected to the common voltage supply unit and comprising a horizontal common voltage line extending in a first direction and a vertical common voltage line extending in a second direction crossing the first direction;
a data line in the display region and extending in the second direction;
a horizontal connection line in the display region, extending in the first direction, and comprising an opening; and
a vertical connection line in the display region, extending in the second direction, and passing through the opening,
wherein the common voltage line covers the opening in the horizontal connection line.

2. The display apparatus of claim 1, wherein the horizontal common voltage line and the vertical common voltage line are integrally formed with each other as a single body.

3. The display apparatus of claim 1, wherein the common voltage line comprises a first shielding pattern, and
the first shielding pattern covers the opening in the horizontal connection line.

4. The display apparatus of claim 3, wherein the horizontal common voltage line, the vertical common voltage line, and the first shielding pattern are integrally formed with one another as a single body.

5. The display apparatus of claim 3, wherein the vertical connection line is above the horizontal connection line, and
the common voltage line and the first shielding pattern are above the vertical connection line.

6. A display apparatus comprising:
a substrate comprising a display region and a peripheral region outside the display region;
a common voltage supply unit in the peripheral region and surrounding at least a portion of the display region;
a horizontal common voltage line electrically connected to the common voltage supply unit and extending in a first direction;
a first vertical common voltage line electrically connected to the common voltage supply unit and extending in a second direction crossing the first direction;
a data line arranged in the display region and extending in the second direction;
a horizontal connection line in the display region and extending in the first direction; and
a first vertical connection line in the display region, extending in the second direction, and electrically connected to the common voltage supply unit,
wherein the first vertical common voltage line comprises a first conductive pattern, and the first vertical common voltage line and the first vertical connection line are electrically connected to each other via a first contact hole in the first conductive pattern.

7. The display apparatus of claim 6, further comprising an organic light-emitting diode on the first vertical common voltage line and comprising a pixel electrode, an emission layer, and an opposite electrode.

8. The display apparatus of claim 7, wherein the pixel electrode covers the first contact hole and the first conductive pattern.

9. The display apparatus of claim 6, wherein the first vertical common voltage line and the first conductive pattern are integrally formed with each other as a single body.

10. The display apparatus of claim 6, further comprising a second vertical connection line spaced apart from the first vertical connection line in the first direction, extending in the second direction, and electrically connected to the common voltage supply unit.

11. The display apparatus of claim 10, further comprising a second vertical common voltage line spaced apart from the first vertical common voltage line in the first direction, extending in the second direction, and electrically connected to the common voltage supply unit.

12. The display apparatus of claim 11, wherein the second vertical common voltage line comprises the first conductive pattern, and
the second vertical common voltage line and the second vertical connection line are electrically connected to each other via the first contact hole in the first conductive pattern.

13. The display apparatus of claim 12, wherein the first vertical common voltage line, the second vertical common voltage line, and the first conductive pattern are integrally formed with one another as a single body.

14. An electronic device comprising:
a substrate comprising a display region and a peripheral region outside the display region;
a common voltage supply unit arranged in the peripheral region and surrounding at least a portion of the display region;
a common voltage line electrically connected to the common voltage supply unit and comprising a horizontal common voltage line extending in a first direction and a vertical common voltage line extending in a second direction crossing the first direction;
a data line arranged in the display region and extending in the second direction;
a horizontal connection line arranged in the display region, extending in the first direction, and comprising an opening; and
a vertical connection line arranged in the display region, extending in the second direction, and passing through the opening,
wherein the common voltage line covers the opening in the horizontal connection line.

15. The electronic device of claim 14, wherein the horizontal common voltage line and the vertical common voltage line are integrally formed with each other as a single body.

16. The electronic device of claim 14, wherein the common voltage line comprises a first shielding pattern, and
wherein the first shielding pattern covers the opening in the horizontal connection line.

17. The electronic device of claim 16, wherein the horizontal common voltage line, the vertical common voltage line, and the first shielding pattern are integrally formed with one another as a single body.

18. The electronic device of claim 16, wherein the vertical connection line is above the horizontal connection line, and
wherein the common voltage line and the first shielding pattern are above the vertical connection line.
